(19) United States
(12) Patent Application Publication
(10) Pub. No.: US 2016/0232397 A1
(43) Pub. Date: Aug. 11, 2016

(54) OPTICAL THIN FILM TRANSISTOR-TYPE FINGERPRINT SENSOR

(71) Applicant: SILICON DISPLAY TECHNOLOGY, Gyeonggi-do (KR)

(72) Inventors: Jin Hyeong YU, Chungcheongnam -do (KR); Ji Ho HUR, Gyeonggi-do (KR); Tae Han GO, Gyeonggi-do (KR)

(73) Assignee: SILICON DISPLAY TECHNOLOGY, Gyeonggi-do (KR)

(21) Appl. No.: 15/022,210

(22) PCT Filed: Sep. 17, 2014
(86) PCT No.: PCT/KR2014/008648

§ 371 Date: Mar. 16, 2016

(30) Foreign Application Priority Data
Sep. 27, 2013 (KR) 10-2013-0114883

(51) Int. Cl. G06K 9/00; H01L 31/173; H01L 31/113

(52) U.S. Cl. CPC G06K 9/00053; H01L 31/1136; H01L 31/173

(57) ABSTRACT

The present invention relates to an optical thin film transistor-type fingerprint sensor, which comprises a backlight unit for irradiating light, including at least one of a red light source, the green light source and the infrared light source; and a photo sensor unit for sensing light irradiated from the backlight unit and reflected by a fingerprint of a user.

### TECHNICAL FIELD

The present invention relates to an optical thin film transistor-type fingerprint sensor.

### BACKGROUND ART

Recently, a capacitive type and an optical type are widely used in a fingerprint sensor.

In general, a capacitive type fingerprint sensor recognizes a fingerprint by sensing capacitance formed by a fingerprint of the human body using a semiconductor device sensitive to a voltage and current.

In contrast, an optical type fingerprint sensor has an advantage of good durability and is configured to include an optical source and an optical sensor. The optical sensor is configured to sense a fingerprint of a user by sensing light emitted from the optical source.

More specifically, in the conventional optical fingerprint sensor, the optical source and the optical sensor are disposed at a specific distance and angle. When light from the optical source is reflected by a fingerprint of a user, the optical sensor may determine whether the fingerprint is sensed or not by sensing the light reflected by the fingerprint.

However, the conventional optical fingerprint sensor had a problem in that if light radiated from a backlight unit is white, a phenomenon in which a fingerprint image is deteriorated if a protection film is attached in order to protect an optical fingerprint sensor.

### DISCLOSURE

### Technical Problem

The present invention has been made keeping in mind the above problems occurring in the prior art, and an object of the present invention is to obtain a more improved fingerprint image because a backlight unit is configured to include at least one of a red optical source, a green optical source, and an infrared optical source.

Furthermore, another object of the present invention is to obtain an improved fingerprint image without generating a phenomenon in which quality of an image is deteriorated although a protection film is formed on the upper side in order to protect an optical fingerprint sensor from static electricity, an external impact, or a scratch.

### Technical Solution

An optical thin film transistor-type fingerprint sensor according to the present embodiment for solving the aforementioned problem is configured to include a backlight unit comprising at least one of a red optical source, a green optical source, and an infrared optical source and radiating light and a photosensor unit sensing light radiated from the backlight unit and reflected by a fingerprint of a user.

In accordance with another embodiment of the present invention, the red optical source may radiate light having a wavelength of 620 to 680 nm.

In accordance with another embodiment of the present invention, the green optical source may radiate light having a wavelength of 540 to 580 nm.

In accordance with another embodiment of the present invention, the infrared optical source may radiate light having a wavelength of 740 nm or more.

In accordance with another embodiment of the present invention, a protection film disposed over the photosensor unit may be further included.

In accordance with another embodiment of the present invention, the protection film may have a thickness of 10 μm or more.

In accordance with another embodiment of the present invention, an adhesive material layer for attaching the protection film over the photosensor unit may be further included.

In accordance with another embodiment of the present invention, the adhesive material layer may have transmittance of 90% or more.

In accordance with another embodiment of the present invention, a thin film transistor for sensing a contact of the fingerprint may be further included.

In accordance with another embodiment of the present invention, the thin film transistor may include any one of Coplanar, staggered, inverted Coplanar, and inverted staggered thin film transistors.

In accordance with another embodiment of the present invention, the thin film transistor may be configured to include an insulating substrate; a semiconductor active layer formed over the insulating substrate; a gate insulating film formed over the semiconductor active layer; a gate electrode formed over the gate insulating film; an interlayer dielectric film formed over the gate electrode; and a source electrode and a drain electrode formed in a via hole formed in the gate insulating film and the interlayer dielectric film.

In accordance with another embodiment of the present invention, the photosensor unit may be configured to include an electrode extended from the drain electrode of the thin film transistor; a semiconductor layer formed over the extended electrode; a transparent electrode formed over the semiconductor layer; a passivation layer formed over the semiconductor layer and the transparent electrode; and a bias electrode formed in a via hole formed in the passivation layer and connected to the transparent electrode.

In accordance with another embodiment of the present invention, an insulating film formed over the passivation layer and the bias electrode may be further included.

### Advantageous Effects

In accordance with an embodiment of the present invention, a more improved fingerprint image can be obtained because the backlight unit is configured to include at least one of the red optical source, the green optical source, and the infrared optical source.

Furthermore, in accordance with an embodiment of the present invention, an improved fingerprint image can be obtained without generating a phenomenon in which quality of an image is deteriorated although the protection film is formed on the optical fingerprint sensor in order to protect the optical fingerprint sensor from static electricity, an external impact, or a scratch.

### DESCRIPTION OF DRAWINGS

FIG. 1 is a cross-sectional view of an optical thin film transistor-type fingerprint sensor in accordance with an embodiment of the present invention.

FIG. 2 is a cross-sectional view of an optical thin film transistor-type fingerprint sensor in accordance with another embodiment of the present invention.

FIG. 3 is a fingerprint image obtained by a conventional optical type thin film transistor-type fingerprint sensor.

FIG. 4 is a fingerprint image obtained by the optical thin film transistor-type fingerprint sensor in accordance with an embodiment of the present invention.

FIG. 5 is a graph showing the results of analysis of resolution of the fingerprint image obtained by the optical thin film transistor-type fingerprint sensor in accordance with an embodiment of the present invention.

### MODE FOR INVENTION

Hereinafter, a preferred embodiment of the present invention is described in detail with reference to the accompanying drawings. In describing embodiments, a detailed description of a related known function or element will be omitted if it is deemed to make the gist of the present invention unnecessarily vague. Furthermore, the size of each element in the drawings may be exaggerated for a description and does not mean a practical size.

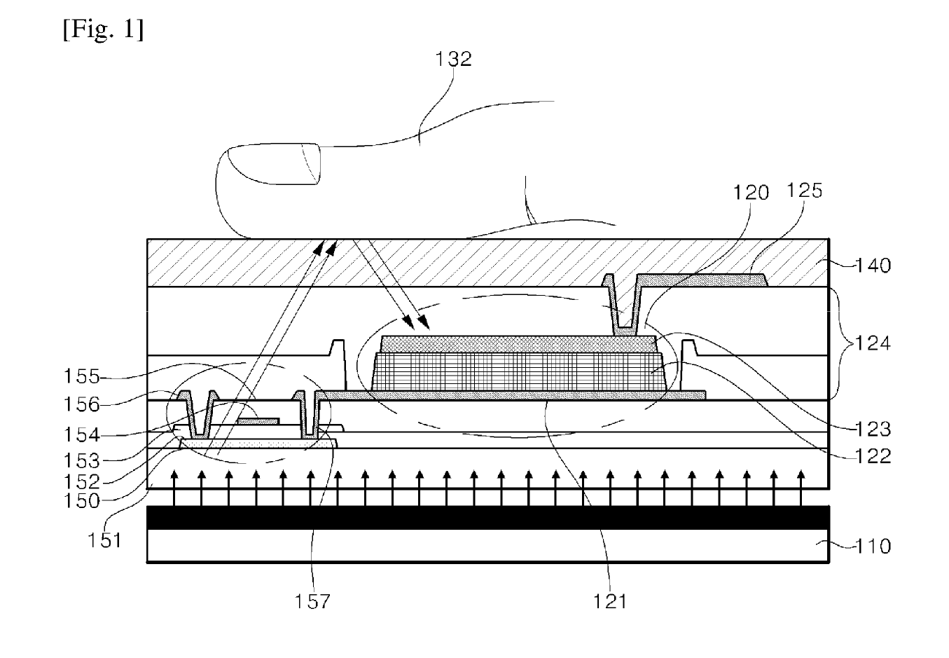

FIG. 1 is a cross-sectional view of an optical thin film transistor-type fingerprint sensor in accordance with an embodiment of the present invention.

The optical thin film transistor-type fingerprint sensor in accordance with an embodiment of the present invention is described with reference to FIG. 1.

As shown in FIG. 1, the optical thin film transistor- type fingerprint sensor in accordance with an embodiment of the present invention includes a backlight unit 110 and a photosensor unit 120 and may be configured to further include a thin film transistor 150.

The backlight unit 110 is configured to include at least one of a red optical source, a green optical source, and an infrared optical source. The backlight unit 110 radiates light upward.

The photosensor unit 120 senses light radiated from the backlight unit 110 and reflected by a fingerprint 132 of a user.

In this case, the red optical source included in the backlight unit 110 may be configured to radiate light having a wavelength of 620 to 680 nm, the green optical source may be configured to radiate light having a wavelength of 540 to 580 nm, and the infrared optical source may be configured to radiate light having a wavelength of 740 nm or more.

If the backlight unit 110 is configured to include at least one of the red optical source, the green optical source, and the infrared optical source as in the present invention, a loss of light can be reduced, diffused reflection can be reduced, and an image of the sensor can be clearly improved because light having a relatively long wavelength is radiated.

Furthermore, the optical thin film transistor-type fingerprint sensor according to the present invention may be configured to further include the thin film transistor 150. In this case, the thin film transistor 150 may include any one of Coplanar, staggered, inverted Coplanar, and inverted staggered thin film transistors.

More specifically, the thin film transistor 150 is configured to include an insulating substrate 151, a semiconductor active layer 152 formed on the insulating substrate 151, a gate insulating film 153 formed on the semiconductor active layer 152, a gate electrode 154 formed on the gate insulating film 153, an interlayer dielectric film 155 formed on the gate electrode 154, and a source electrode 156 and a drain electrode 157 formed in a via hole formed in the gate insulating film 155 and the gate insulating film 153.

Furthermore, the photosensor unit 120 may be configured to include a semiconductor layer 122 formed on an electrode 121 extended from the drain electrode of the thin film transistor, a transparent electrode 123 formed on the semiconductor layer 122, a passivation layer 124 formed on the semiconductor layer 122 and the transparent electrode 123, and a bias electrode 125 formed in a via hole formed in the passivation layer 124 and connected to the transparent electrode 123.

Furthermore, an insulating film 140 may be formed on the passivation layer 124 and the bias electrode 125.

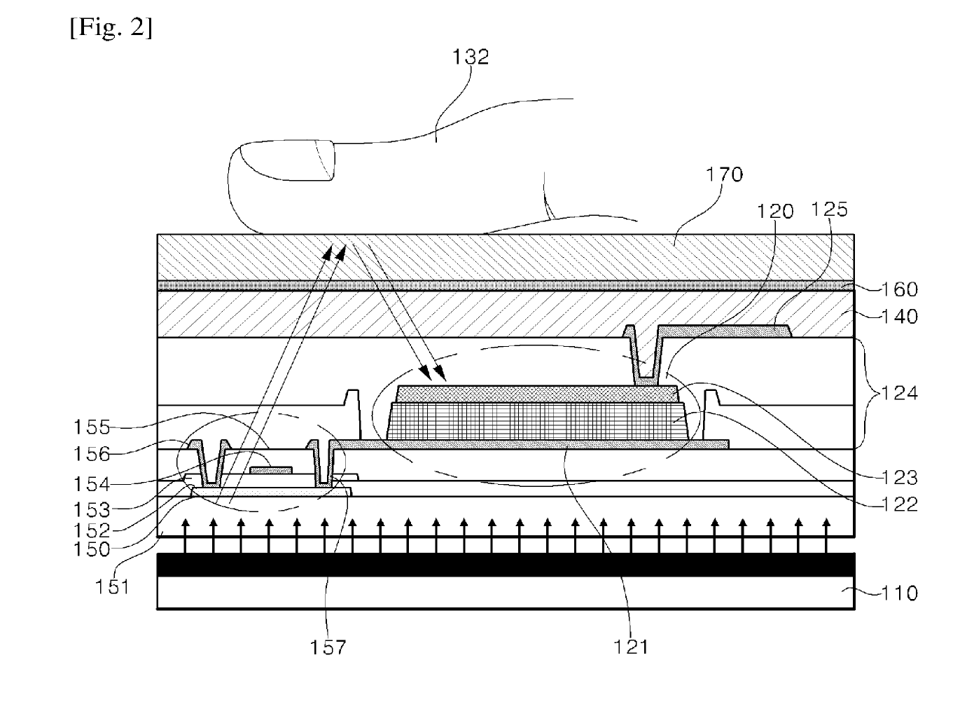

FIG. 2 is a cross-sectional view of an optical thin film transistor-type fingerprint sensor in accordance with another embodiment of the present invention.

The optical thin film transistor-type fingerprint sensor in accordance with another embodiment of the present invention is described with reference to FIG. 2.

As shown in FIG. 2, the optical thin film transistor-type fingerprint sensor in accordance with another embodiment of the present invention includes the backlight unit 110 and the photosensor unit 120 and may be configured to further include the thin film transistor 150, an adhesive material layer 160 and a protection film 170.

As in the embodiment of FIG. 1, even in the embodiment of FIG. 2, the backlight unit 110 is configured to include at least one of a red optical source, a green optical source, and an infrared optical source. The backlight unit 110 radiates light upward.

The photosensor unit 120 senses light radiated from the backlight unit 110 and reflected by the fingerprint 132 of the user. The red optical source included in the backlight unit 110 may be configured to radiate light having a wavelength of 620 to 680 nm, the green optical source may be configured to radiate light having a wavelength of 540 to 580nm, and the infrared optical source may be configured to radiate light having a wavelength of 740 nm or more.

Furthermore, the optical thin film transistor-type fingerprint sensor according to the present invention may be configured to further include the thin film transistor 150. In this case, the thin film transistor 150 may include any one of Coplanar, staggered, inverted Coplanar, and inverted staggered thin film transistors.

More specifically, the thin film transistor 150 is configured to include the insulating substrate 151, the semiconductor active layer 152 formed on the insulating substrate 151, the gate insulating film 153 formed on the semiconductor active layer 152, the gate electrode 154 formed on the gate insulating film 153, the interlayer dielectric film 155 formed on the gate electrode 154, and the source electrode 156 and the drain electrode 157 formed in the via hole formed in the gate insulating film 155 and the gate insulating film 153.

Furthermore, the photosensor unit 120 may be configured to include the semiconductor layer 122 formed on the electrode 121 extended from the drain electrode of the thin film transistor, the transparent electrode 123 formed on the semiconductor layer 122, the passivation layer 124 formed on the semiconductor layer 122 and the transparent electrode 123, and the bias electrode 125 formed in the via hole formed in the passivation layer 124 and connected to the transparent electrode 123. The insulating film 140 may be formed on the passivation layer 124 and the bias electrode 125.

In the embodiment of FIG. 2, the protection film 170 may be further formed over the insulating film 140 the photosensor unit 120 configured as described above.

In this case, the protection film 170 may have a thickness of 10 μm or more. In order to attach the protection film 170, the adhesive material layer 160 may be used.

The adhesive material layer 160 may be made of a material having transmittance of 90% or more. The protection film 170 and the adhesive material layer 160 may be configured to have the same refractive index in order to prevent the generation of an optical coupling phenomenon.

If the backlight unit 110 is configured to include at least one of the red optical source, the green optical source, and the infrared optical source as in the present invention, a more improved fingerprint image can be obtained. Accordingly, although the protection film 170 is formed on the upper side in order to protect the optical thin film transistor-type fingerprint sensor from an external impact or a scratch, an improved fingerprint image can be obtained without generating a phenomenon in which quality of an image is deteriorated.

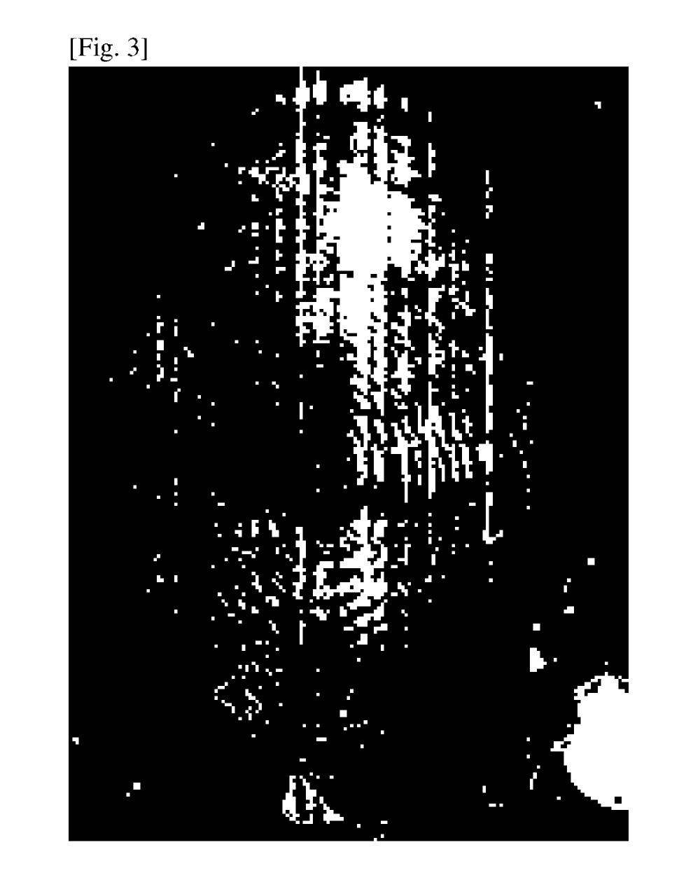

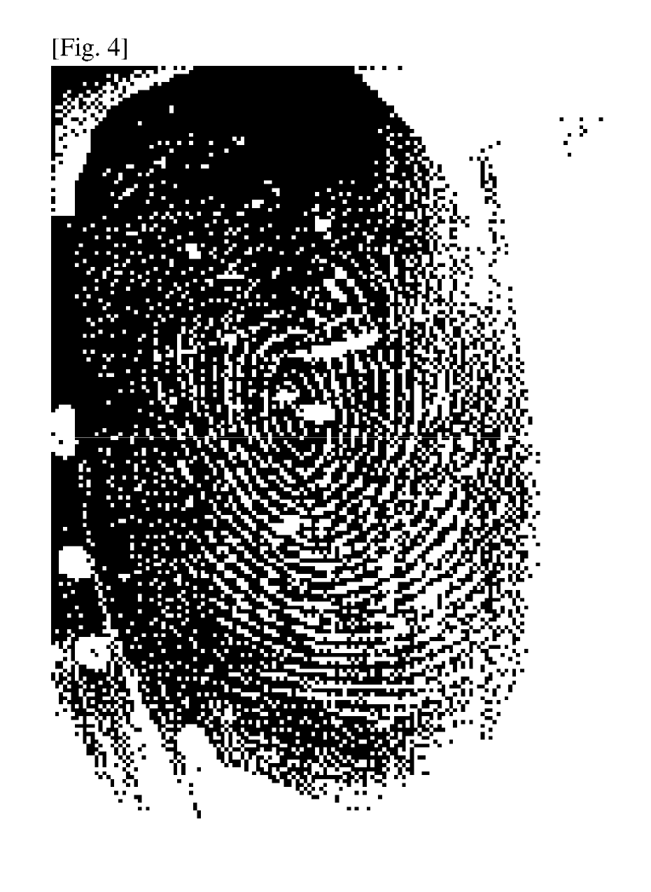

FIG. 3 is a fingerprint image obtained by the conventional optical type thin film transistor-type fingerprint sensor, and FIG. 4 is a fingerprint image obtained by the optical thin film transistor-type fingerprint sensor in accordance with an embodiment of the present invention.

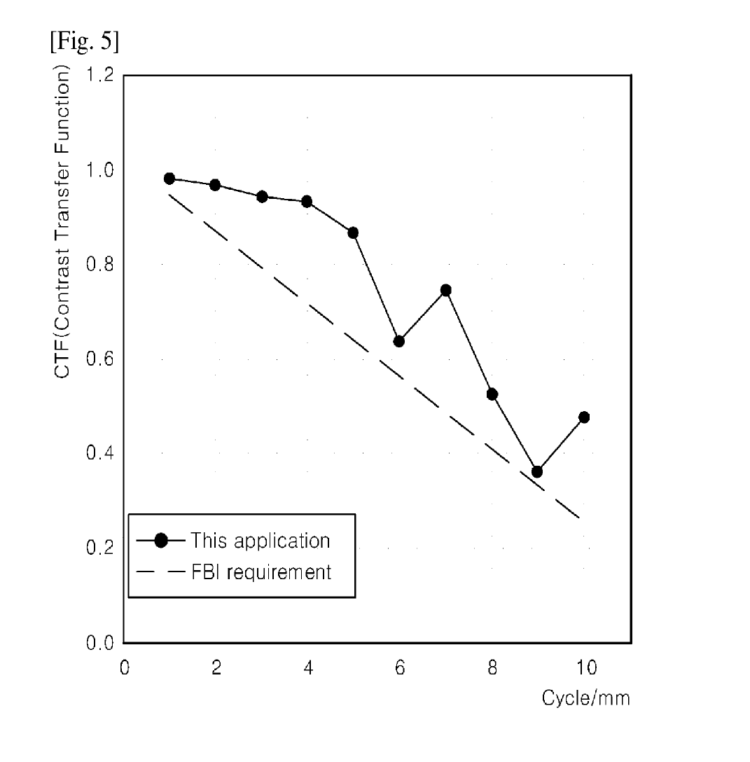

Furthermore, FIG. 5 is a graph showing the results of analysis of resolution of the fingerprint image obtained by the optical thin film transistor-type fingerprint sensor in accordance with an embodiment of the present invention.

FIG. 3 is a fingerprint image obtained by the conventional optical type thin film transistor-type fingerprint sensor. More specifically, FIG. 3 is a fingerprint image obtained by the optical thin film transistor-type fingerprint sensor using a backlight unit including a white optical source and a protection film of a PET material of 50 μm in thickness in which water is used as an adhesive material layer.

Meanwhile, FIG. 4 is a fingerprint image obtained by the optical thin film transistor-type fingerprint sensor using the backlight unit including the red optical source in accordance with an embodiment of the present invention and the protection film of a PET material of 50 μm in thickness in which water is used as the adhesive material layer.

As shown in FIG. 4, in accordance with an embodiment of the present invention, a clearer fingerprint image can be obtained compared to the conventional fingerprint image of FIG. 3.

Furthermore, as shown in FIG. 5, it may be seen that the fingerprint image obtained by the optical thin film transistor-type fingerprint sensor in accordance with an embodiment of the present invention satisfies all criteria according to FBI requirements (Appendix F), that is, fingerprint quality criteria based on resolution.

In the detailed description of the present invention, detailed embodiments have been described. However, the present invention may be modified in various ways without departing from the scope of the present invention. Accordingly, the technical spirit of the present invention should not be limited to the aforementioned embodiments, but should be defined by the appended claims and equivalent thereof.

1. An optical thin film transistor-type fingerprint sensor, comprising:
a backlight unit comprising at least one of a red optical source, a green optical source, and an infrared optical source and radiating light; and
a photosensor unit sensing light radiated from the backlight unit and reflected by a fingerprint of a user.

2. The optical thin film transistor-type fingerprint sensor of claim 1, wherein the red optical source radiates light having a wavelength of 620 to 680 nm.

3. The optical thin film transistor-type fingerprint sensor of claim 1, wherein the green optical source radiates light having a wavelength of 540 to 580 nm.

4. The optical thin film transistor-type fingerprint sensor of claim 1, wherein the infrared optical source radiates light having a wavelength of 740 nm or more.

5. The optical thin film transistor-type fingerprint sensor of claim 1, further comprising a protection film disposed over the photosensor unit.

6. The optical thin film transistor-type fingerprint sensor of claim 5, wherein the protection film has a thickness of 10 μm or more.

7. The optical thin film transistor-type fingerprint sensor of claim 5, further comprising an adhesive material layer for attaching the protection film over the photosensor unit.

8. The optical thin film transistor-type fingerprint sensor of claim 7, wherein the adhesive material layer has transmittance of 90% or more.

9. The optical thin film transistor-type fingerprint sensor of claim 1, further comprising a thin film transistor for sensing a contact of the fingerprint.

10. The optical thin film transistor-type fingerprint sensor of claim 9, wherein the thin film transistor comprises any one of Coplanar, staggered, inverted Coplanar, and inverted staggered thin film transistors.

11. The optical thin film transistor-type fingerprint sensor of claim 9, wherein the thin film transistor comprises:
an insulating substrate;
a semiconductor active layer formed over the insulating substrate;
a gate insulating film formed over the semiconductor active layer;
a gate electrode formed over the gate insulating film;
an interlayer dielectric film formed over the gate electrode; and
a source electrode and a drain electrode formed in a via hole formed in the gate insulating film and the interlayer dielectric film.

12. The optical thin film transistor-type fingerprint sensor of claim 11, wherein the photosensor unit comprises:
an electrode extended from the drain electrode of the thin film transistor;
a semiconductor layer formed over the extended electrode;
a transparent electrode formed over the semiconductor layer;
a passivation layer formed over the semiconductor layer and the transparent electrode; and
a bias electrode formed in a via hole formed in the passivation layer and connected to the transparent electrode.

13. The optical thin film transistor-type fingerprint sensor of claim 12, further comprising an insulating film formed over the passivation layer and the bias electrode.
